(19) United States
(12) Patent Application Publication
(10) Pub. No.: US 2006/0115910 A1
(43) Pub. Date: Jun. 1, 2006

(54) Method for predicting lifetime of insulating film

(75) Inventor: Kenji Okada, Ibaraki (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/283,993

(22) Filed: Nov. 22, 2005

(30) Foreign Application Priority Data
Nov. 26, 2004 (JP) 2004-342078
Sep. 29, 2005 (JP) 2005-284719

(51) Int. Cl. H01L 21/66

(52) U.S. Cl. 438/17

(57) ABSTRACT

The type of subordinate carrier in current flowing through a target insulating film is determined. Then, the total amount Q of subordinate carriers injected until an insulating-film sample causes dielectric breakdown under electrical stress application to the insulating-film sample is obtained. Thereafter, the current amount I of the subordinate carrier flowing through the target insulating film to which a stress voltage at which a lifetime T_{BD} of the target insulating film is to be obtained is applied is obtained. Lastly, the lifetime T_{BD} is calculated based on Equation (1):
∫₀^{T}^{_{BD}}Idt=Q (1)

### BACKGROUND OF THE INVENTION

(1) Field of the Invention

The present invention relates to methods for predicting the lifetimes of insulating films, particularly gate insulating films, capacitive insulating films or interlayer insulating films for use in semiconductor devices.

(2) Description of the Related Art

With recent enhancement of the integration degree, functions and speed of semiconductor integrated circuit devices, the thicknesses of gate insulating films have decreased, resulting in that conventional silicon dioxide films (SiO₂ films) or nitrogen-introduced silicon oxide films (SiOₓN_{y} films) have become insufficient to satisfy standard values for, for example, the amount of leakage current. In view of this, gate insulating films using new insulating-film materials having dielectric constants higher than that of SiO₂, e.g., hafnium-based materials (such as HfOₓ, HfSiOₓ, HfAlOₓ and HfOₓN_{y}), are proposed. Such insulating films will be hereinafter referred to as high-k films. These high-k films generally do not have a single-layer structure made of a high-k film but have a multilayer structure including a high-k film and either a silicon oxide film (e.g., a SiO₂ film or a SiOₓN_{y} film) or a silicon nitride film (a Si₃N₄ film), for example. Accordingly, there is a structural difference as well as a material difference between a gate insulating film using a conventional silicon oxide film and a gate insulating film including a high-k film. However, to predict the lifetime of a gate insulating film including a high-k film, a model (see, I. C. Chen, S. E. Holland, and C. Hu: “Electrical Breakdown in Thin Gate and Tunneling Oxides”, IEEE Trans. Elec. Dev. 32 (1985) pp. 413-422 and J. W. McPherson, D. A. Baglee: “Acceleration Factors for Thin Gate Oxide Stressing”, Int. Rel. Phys. Symposium (1985) pp. 1-5) for use in predicting the dielectric breakdown lifetime of a conventional silicon oxide film is also used.

### SUMMARY OF THE INVENTION

However, a recently-used gate insulating film including a high-k film which has been used differs in material and structure from a conventional gate oxide film as described above, so that it might be impossible to apply a conventional model thereto without change. In addition, it has yet to be found what types of model is appropriate for predicting the lifetime of a gate insulating film including a high-k film.

On the other hand, the range of uses of high-k films is expected to increase in future. Specifically, it has been considered to use a high-k film for a tunnel insulating film in a flash memory and, further, a so-called interlayer insulating film between a floating gate and a control gate. A silicon nitride film having a dielectric constant higher than that of a silicon oxide film has been already used in an insulating film for accumulating charge in, for example, a MONOS (metal oxide nitride oxide silicon) flash memory, a SONOS (silicon oxide nitride oxide silicon) flash memory or a so-called NROM (nitride read only memory) type flash memory. However, an insulating film having a higher dielectric constant as described above is expected to be employed. In addition, a high-k film is also expected to be used for a capacitive insulating film in a memory device.

Insulating films including insulating films for various uses as described above are herein collectively called “gate insulating films”. The present invention is applicable to these “gate insulating films”.

It is therefore an object of the present invention to provide an evaluation method for easily and accurately obtain the dielectric breakdown lifetime of a gate insulating film made of a single-layer film such as a high-k film including a silicon nitride film or a multilayer film as a stack of two or more layers including such a high-k film, in a semiconductor device.

To achieve the object, a first method for predicting a lifetime of an insulating film according to the present invention is a method for predicting a dielectric breakdown lifetime of a target insulating film including a portion having a dielectric constant higher than that of a silicon oxide film. The first method includes the steps of: (a) determining the type of subordinate carrier in current flowing through the target insulating film; (b) obtaining the total amount of subordinate carriers injected until the target insulating film to which a given voltage is applied causes dielectric breakdown; (c) obtaining the current amount of the subordinate carrier flowing through the target insulating film to which a predetermined voltage is applied; and (d) obtaining a dielectric breakdown lifetime until the target insulating film to which the predetermined voltage is applied causes dielectric breakdown, based on the finding that the total amount obtained at the step (b) is constant regardless of the applied voltage and based on the current amount obtained at the step (c).

In the first method, the step (c) preferably further includes the steps of: (e) measuring a time-dependent change of the amount of stress induced leakage current (SILC) flowing through the target insulating film to which a reference voltage is applied, the time-dependent change occurring under electrical stress application using a first stress voltage; (f) measuring a time-dependent change of the amount of SILC flowing through the target insulating film to which the reference voltage is applied, the time-dependent change occurring under electrical application using a second stress voltage; (g) obtaining the ratio between the amount of deterioration of the target insulating film caused by application of the first stress voltage and the amount of deterioration of the target insulating film caused by application of the second stress voltage, based on the time-dependent changes of the SILC amount measured at the steps (e) and (f); and (h) obtaining the ratio between the current amount of the subordinate carrier in current flowing through the target insulating film to which the first stress voltage is applied and the current amount of the subordinate carrier in current flowing through the target insulating film to which the second stress voltage is applied, based on the ratio obtained at the step (g).

A second method for predicting a lifetime of an insulating film according to the present invention is a method for predicting a dielectric breakdown lifetime of a target insulating film including a portion having a dielectric constant higher than that of a silicon oxide film. The second method includes the steps of: (a) obtaining a dielectric breakdown lifetime until the target insulating film causes dielectric breakdown under electrical stress application using a first stress voltage; (b) evaluating a time-dependent change of the amount of current flowing through the target insulating film to which a reference voltage is applied, the time-dependent change occurring under electrical stress application using the first stress voltage; (c) evaluating a time-dependent change of the amount of current flowing through the target insulating film to which the reference voltage is applied, the time-dependent change occurring under electrical stress application using a second stress voltage; (d) obtaining the ratio between the amount of deterioration of the target insulating film caused by application of the first stress voltage and the amount of deterioration of the target insulating film caused by application of the second stress voltage, based on the time-dependent changes evaluated at the steps (b) and (c); and (e) obtaining a dielectric breakdown lifetime until the target insulating film causes dielectric breakdown under electrical stress application using the second stress voltage, based on the dielectric breakdown lifetime obtained at the step (a) and the ratio obtained at the step (d).

A third method for predicting a lifetime of an insulating film according to the present invention is a method for predicting a dielectric breakdown lifetime of a target insulating film including a portion having a dielectric constant higher than that of a silicon oxide film. The third method includes the steps of: (a) determining the type of subordinate carrier in current flowing through the target insulating film; (b) obtaining the total amount Q of subordinate carriers injected until an insulating-film sample causes dielectric breakdown under electrical stress application to the insulating-film sample; (c) obtaining the current amount I of the subordinate carrier flowing through the gate insulating film to which a stress voltage at which a lifetime T_{BD} of the target insulating film is to be obtained is applied; and (d) calculating the lifetime T_{BD} based on Equation (1):
∫₀^{T}^{_{BD}}Idt=Q (1)

A fourth method for predicting a lifetime of an insulating film according to the present invention is a method for predicting a dielectric breakdown lifetime of a target insulating film including a portion having a dielectric constant higher than that of a silicon oxide film. The fourth method includes the steps of: (a) obtaining a dielectric breakdown lifetime T₀ until the target insulating film causes dielectric breakdown under application of a given stress voltage V₀ to the target insulating film; (b) repeatedly performing electrical stress application using the given stress voltage V₀ and current-voltage characteristic evaluation on the target insulating film o, thereby evaluating a time-dependent change of the amount of SILC flowing through the target insulating film; (c) repeatedly performing electrical stress application using a stress voltage V at which a lifetime T_{BD} of the target insulating film is to be obtained and current-voltage characteristic evaluation on the target insulating film, thereby evaluating a time-dependent change of the amount of SILC flowing through the gate insulating film; (d) multiplying a stress time for the time-dependent change of the SILC amount obtained at the step (c) by a given factor, thereby obtaining a multiplying factor X with which the time-dependent change with the multiplied stress time substantially agrees with the time-dependent change of the SILC amount obtained at the step (b); and (e) calculating the lifetime T_{BD} based on Equation (2):
T_{BD}=T₀/X (2)

A fifth method for predicting a lifetime of an insulating film according to the present invention is a method for predicting a dielectric breakdown lifetime of a target insulating film including a portion having a dielectric constant higher than that of a silicon oxide film. The fifth method includes the steps of: (a) obtaining a dielectric breakdown lifetime T₀ until the target insulating film to which a given stress voltage V₀ is applied causes dielectric breakdown; (b) fitting previously-obtained stress voltage dependence of a dielectric breakdown lifetime of an insulating-film sample, to the dielectric breakdown lifetime T₀ of the target insulating film at the given stress voltage V₀; and (c) obtaining a dielectric breakdown lifetime T_{BD} until the target insulating film to which a predetermined stress voltage V is applied causes dielectric breakdown, based on the result of the fitting.

In the fifth method, in the step (b), the stress voltage dependence of the dielectric breakdown lifetime of the insulating-film sample is preferably obtained based on stress voltage dependence of the voltage acceleration factor of the dielectric breakdown lifetime of the insulating-film sample.

A sixth method for predicting a lifetime of an insulating film according to the present invention is a method for predicting a dielectric breakdown lifetime of a target insulating film including a portion having a dielectric constant higher than that of a silicon oxide film. The sixth method includes the steps of: (a) determining the type of subordinate carrier in current flowing through the target insulating film; (b) obtaining the total amount of subordinate carriers injected until an insulating-film sample causes dielectric breakdown; (c) obtaining the current amount of the subordinate carrier flowing through the target insulating film to which a given voltage is applied; (d) obtaining a dielectric breakdown lifetime until the target insulating film to which the given voltage is applied causes dielectric breakdown, based on the finding that the total amount obtained at the step (b) is constant regardless of the applied voltage and based on the current amount obtained at the step (c); and (e) fitting previously-obtained stress voltage dependence of a dielectric breakdown lifetime of an insulating-film sample, to the dielectric breakdown lifetime at the given voltage obtained at the step (d); and (f) obtaining a dielectric breakdown lifetime until the target insulating film to which a predetermined stress voltage V is applied causes dielectric breakdown, based on the result of the fitting.

In the first through sixth methods, the portion having a high dielectric constant is preferably a high-k film.

In the first, third or sixth method, the total amount of injected intrinsic subordinate carriers is preferably used as the total amount of the injected subordinate carriers.

In the first, third or sixth method, the current amount of intrinsic subordinate carrier is preferably used as the current amount of the subordinate carrier.

A method for predicting the lifetime of an insulating film according to the present invention provides a guideline so as to enable prediction of the lifetime of a gate insulating film to which a given stress voltage is applied based on a dielectric breakdown lifetime until the gate insulating film causes dielectric breakdown under application of a stress voltage at which the lifetime is actually measured. With this method, the lifetime of a gate insulating film is obtained more easily and accurately. Accordingly, the present invention is very useful as a method for predicting the dielectric breakdown lifetime of a gate insulating film, for example.

### BRIEF DESCRIPTION OF THE DRAWINGS

FIGS. 1A and 1B are views showing cross-sectional structures of a capacitor and a transistor, respectively, to which a method for predicting the lifetime of an insulating film according to a first embodiment of the present invention is to be applied.

FIG. 2 is a graph showing stress voltage (absolute value) dependence of the dielectric breakdown lifetime when a stress gate voltage (a constant-voltage stress) is applied to a sample having the MOS capacitor structure illustrated in FIG. 1A.

FIG. 3 is a graph showing a result of evaluation in which gate current in negative and positive gate voltage ranges is divided into source/drain current and well current, using a pMOSFET sample and an nMOSFET sample both having the MOSFET structure illustrated in FIG. 1B.

FIGS. 4A and 4B are graphs showing results of plotting, with respect to stress voltages, the total amount of electrons (Qₑₗ) and the total amount of holes (Qₕₒₗₑ) injected until dielectric breakdown occurs obtained by integrating the electron current amount and the hole current amount, respectively, obtained by the lifetime prediction method of the first embodiment using the time to the occurrence of dielectric breakdown. FIG. 4A shows a result obtained in a case where a stress gate voltage which is a negative bias is applied. FIG. 4B shows a result obtained in a case where a stress gate voltage which is a positive bias is applied.

FIGS. 5A and 5B are graphs showing results of plotting, with respect to stress voltages, stress voltage dependencies of electron current amount (Iₑₗ) and hole current amount (Iₕₒₗₑ) measured by using carrier separation in the lifetime prediction method of the first embodiment. FIG. 5A is a result obtained in a case where a stress gate voltage which is a negative bias is applied. FIG. 5B is a result obtained in a case where a stress gate voltage which is a positive bias is applied.

FIGS. 6A and 6B are graphs showing results of plotting changes of an SILC amount at a given gate voltage in a case where various stress gate voltages are repeatedly applied to an insulating film sample in the lifetime prediction method of the first embodiment. FIG. 6A shows a result obtained in a case where a stress gate voltage which is a negative bias is applied. FIG. 6B shows a result obtained in a case where a stress gate voltage which is a positive bias is applied.

FIG. 7 shows a flow of the lifetime prediction method of the first embodiment.

FIG. 8 is a graph showing results, made by the present inventor, of plotting stress time dependence of the SILC amount under application of constant-voltage stress gate voltages of +3.5 V and +4.25 V and the SILC amount under application of a constant-voltage stress gate voltage of +3.5 V, with the stress time reduced to 1/200.

FIG. 9 shows a flow of a method for predicting the lifetime of an insulating film according to a second embodiment of the present invention.

FIG. 10 a graph showing a result of plotting stress voltage dependence of the voltage acceleration factor γ of the dielectric breakdown lifetime (T_{BD}) of a gate insulating film made of various materials when a constant-voltage stress is applied to the gate insulating film.

FIG. 11 is a graph showing stress voltage dependence of the dielectric breakdown lifetime (T_{BD}) obtained by the present inventor based on the stress voltage dependence of the voltage acceleration factor γ in the dielectric breakdown lifetime (T_{BD}) of the gate insulating film made of various materials under application of a constant-voltage stress.

FIG. 12 shows a flow of a method for predicting the lifetime of an insulating film (e.g., a gate insulating film) according to a third embodiment of the present invention.

FIG. 13 shows a flow of a method for predicting the lifetime of an insulating film (e.g., a gate insulating film) according to a fourth embodiment of the present invention.

### DETAILED DESCRIPTION OF THE INVENTION

### EMBODIMENT 1

Hereinafter, a method for predicting the lifetime of an insulating film according to a first embodiment of the present invention will be described with reference to the drawings.

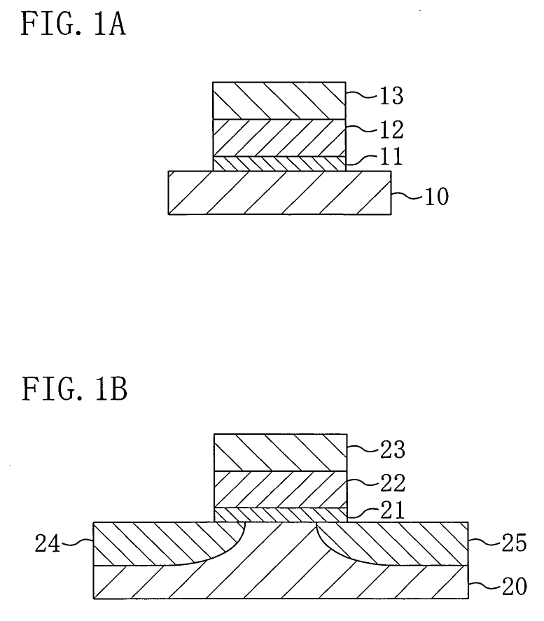

FIGS. 1A and 1B schematically illustrate cross-sectional shapes of samples for use in measurement of data which will be described later. FIG. 1A illustrates a cross-sectional structure of a metal oxide semiconductor (MOS) capacitor and FIG. 1B illustrates a cross-sectional structure of a metal oxide semiconductor field-effect transistor (MOSFET). An insulating film to which the present invention is applied is a gate insulating film having a multilayer structure including a high dielectric constant (high-k) film and a SiO₂ film, for example, and is not limited to an oxide film. Therefore, the structure of the present invention should be written as a MIS (metal insulator semiconductor) structure, not a MOS structure, in a strict sense. However, according to the custom, “MOS” is herein also used in a case where a multilayer insulating film or an insulating film made of an insulating material other than oxide is used. That is, a “MOS” structure is not limited to a structure using oxide.

In a MOS capacitor illustrated in FIG. 1A, a gate insulating film made up of a SiO₂ film 11 as a lower layer and a HfAlOₓ film 12 as an upper layer is formed on a silicon substrate 10, and a gate electrode 13 made of polysilicon is formed on the gate insulating film.

In a MOSFET illustrated in FIG. 1B, a gate insulating film made up of a SiO₂ film 21 as a lower layer and a HfAlOₓ film 22 as an upper layer is formed on a silicon substrate 20, and a gate electrode 23 made of polysilicon is formed on the gate insulating film. Source 24 and drain 25 are formed in the silicon substrate 20 at both sides of the gate electrode 23.

Phosphorus is implanted as an impurity in the gate electrode 13 of the MOS capacitor and the gate electrode 23 of the MOSFET. The HfAlOₓ film 12 of the MOS capacitor and the HfAlOₓ film 22 of the MOSFET are high-k films. The SiO₂ film 11 of the MOS capacitor and the SiO₂ film 21 of the MOSFET are interlayer (IL) films or lower insulating films.

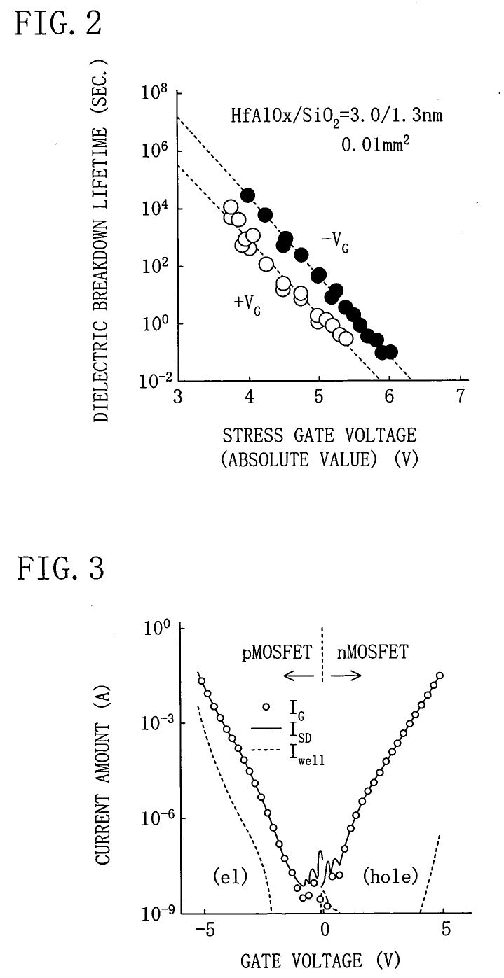

FIG. 2 shows stress voltage (absolute value) dependence of the dielectric breakdown lifetime when a stress gate voltage (a constant-voltage stress) is applied to a sample having the MOS capacitor structure illustrated in FIG. 1A. Specifically, in FIG. 2, solid circles represent stress voltage (absolute value) dependence of the dielectric breakdown lifetime when a negative stress gate voltage (−V_{G}) is applied to a sample in which the MOS capacitor structure illustrated in FIG. 1A is formed on a p-type substrate, and open circles represent stress voltage (absolute value) dependence of the dielectric breakdown lifetime when a positive stress gate voltage (+V_{G}) is applied to a sample in which the MOS capacitor structure illustrated in FIG. 1A is formed on an n-type substrate. In these samples, the capacitor structure has an area of 0.01 mm², the HfAlOₓ film 12 has a thickness of 3.0 nm and the SiO₂ film 11 has a thickness of 1.3 nm.

As shown in FIG. 2, the dielectric breakdown lifetime linearly changes on a log-linear scale within a measurement condition range for both polarities of the stress gate voltage.

FIG. 3 shows a result of evaluating gate current (I_{G}, represented by open circles) using a pMOSFET sample and an nMOSFET sample both having the MOSFET structure illustrated in FIG. 1B. In FIG. 3, the gate current is divided into source/drain current (ISD, represented by solid lines) and well current (I_{Well}, represented by broken lines) in negative and positive gate voltage ranges. In this graph, “well” means a terminal for obtaining the potential at the substrate of the MOSFET structure illustrated in FIG. 1B. The types of carriers in the source/drain current and the well current change depending on the polarity of the stress. In those samples, carriers in the source/drain current are electrons and carriers in the well current are holes in the positive gate bias range, whereas carriers in the source/drain current are holes and carriers in the well current are electrons in the negative gate bias range. That is, as shown in FIG. 3, with respect to gate current in the samples, dominant (majority) carriers are electrons and subordinate (minority) carriers are holes in the positive gate bias range, whereas dominant carriers are holes and subordinate carriers are electrons in the negative gate bias range.

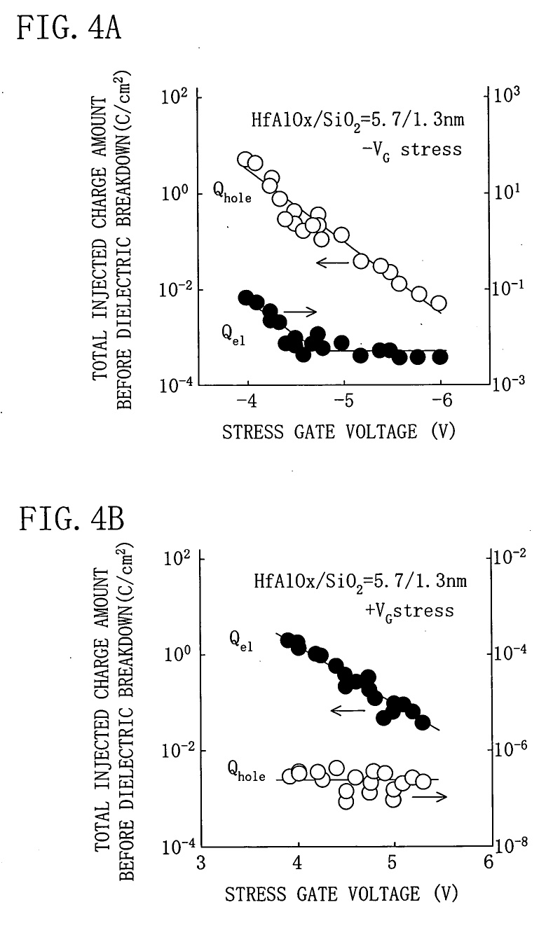

The current amounts of electrons and holes thus obtained are integrated using the time elapsed before the occurrence of dielectric breakdown, thereby obtaining the total amounts of electrons (Qₑₗ) and holes (Qₕₒₗₑ) injected until dielectric breakdown occurs. FIGS. 4A and 4B show results of plotting the amounts Qₑₗ and Qₕₒₗₑ with respect to stress voltages. FIG. 4A shows a result obtained in a case where a stress gate voltage which is a negative bias is applied. FIG. 4B shows a result obtained in a case where a stress gate voltage which is a positive bias is applied. The results shown in FIGS. 4A and 4B are obtained using a sample including a multilayer gate insulating film made up of a SiO₂ film as a lower layer having a thickness of 1.3 nm and a HfAlOₓ film as an upper layer having a thickness of 5.7 mm. In FIG. 4A, solid circles represent Qₑₗ (the right ordinate) and open circles represent Qₕₒₗₑ (the left ordinate). In FIG. 4B, solid circles represent Qₑₗ (the left ordinate) and open circles represent Qₕₒₗₑ (the right ordinate).

As shown in FIG. 4A, in the case where a negative bias stress gate voltage is applied, Qₕₒₗₑ linearly decreases as the absolute value of the stress voltage increases. On the other hand, Qₑₗ decreases as the absolute value of the stress voltage increases in an initial range. However, in a range where the absolute value of the stress voltage is about 4.5 V or more, Qₑₗ is substantially constant independently of the stress voltage. As shown in FIG. 4B, in the case where a positive bias stress gate voltage is applied, Qₑₗ linearly decreases as the stress voltage increases, whereas Qₕₒₗₑ is substantially constant independently of the stress voltage.

As described above, Qₑₗ is constant under application of a negative bias stress gate voltage and Qₕₒₗₑ is constant under application of a positive bias stress gate voltage. That is, the total amount of injected subordinate carriers is constant independently of the level of the applied stress voltage.

It is expected that the use of the foregoing findings enables lifetime prediction. However, as shown in FIG. 4A, the total amount of injected subordinate carriers obtained by measurement is not always constant in a certain stress voltage range, and can change depending on a stress voltage. This phenomenon might be an obstacle in using the finding for the lifetime prediction. Now, a result of a study made by the present inventor on a cause of the change of the total amount of injected subordinate carriers depending on a stress voltage will be described.

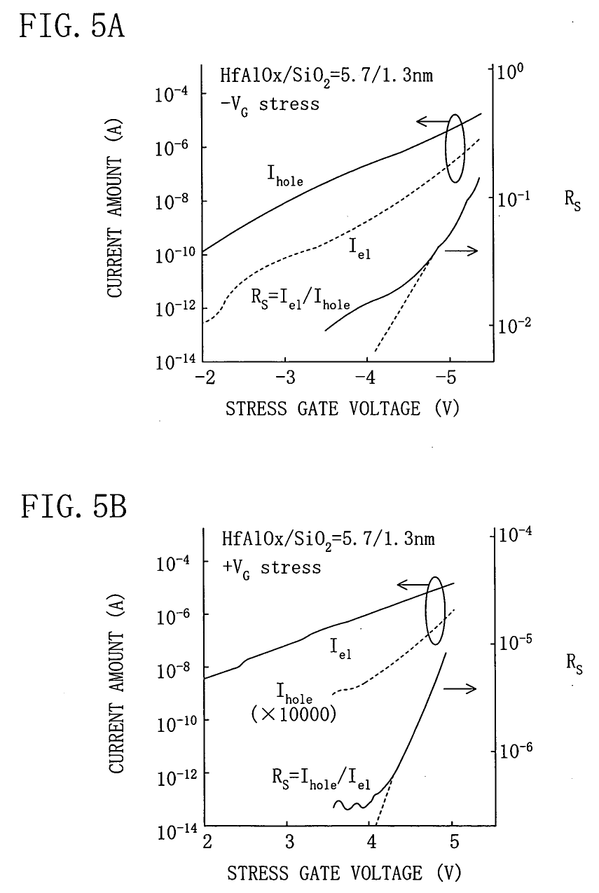

FIGS. 5A and 5B show results of plotting, with respect to stress voltages, stress voltage dependencies of electron current amount (Iₑₗ) and hole current amount (Iₕₒₗₑ) measured by using a carrier separation method similar to that used for FIG. 3. FIG. 5A is a result obtained in a case where a stress gate voltage which is a negative bias is applied. FIG. 5B is a result obtained in a case where a stress gate voltage which is a positive bias is applied. The results shown in FIGS. 5A and 5B are obtained using a sample including a multilayer gate insulating film made up of a SiO₂ film as a lower layer having a thickness of 1.3 nm and a HfAlOₓ film as an upper layer having a thickness of 5.7 nm. On the right ordinates in FIGS. 5A and 5B, Rₛ, which is the ratio of the current amount of subordinate carrier to the current amount of dominant carrier, is plotted. For simplicity, in FIG. 5B, the value obtained by multiplying Iₕₒₗₑ by 10000 is plotted. In FIGS. 5A and 5B, since subordinate carriers and dominant carriers are replaced with each other depending on the stress polarity, denominator and numerator of Rₛ are replaced with each other.

With respect to stress voltage dependence of Rₛ, as shown in FIGS. 5A and 5B, Rₛ linearly changes in a high-voltage range regardless of the polarity of the stress voltage. In FIGS. 5A and 5B, the line fitted to Rₛ in the high-voltage range is shown as a broken line. In a low-voltage range, however, the Rₛ value is larger than this broken line and deviates from the line. More specifically, the Rₛ value is on the line under application of a stress gate voltage of about 4.7 V (absolute value) or higher for the negative bias and under application of a stress gate voltage of about 4.3 V or higher for the positive bias. These voltage values substantially agree with stress-voltage ranges where the total amount of injected subordinate carriers is constant as shown in FIGS. 4A and 4B. As shown in FIG. 4A, the total amount of injected subordinate carriers increases in the stress-voltage range of about 4.3 V (absolute value) or lower for the negative bias. This agrees with a behavior in which the Rₛ value is larger than the broken line (i.e., the line fitted to Rₛ in the high-voltage range).

From the foregoing results, if the assumption is made that the current amount of subordinate carrier contributing dielectric breakdown also linearly changes in a low-voltage range in actual operation, the total amount of injected subordinate carriers is expected to be constant in all the stress-voltage range. Hereinafter, the validity of this assumption will be explained with reference to experimental results.

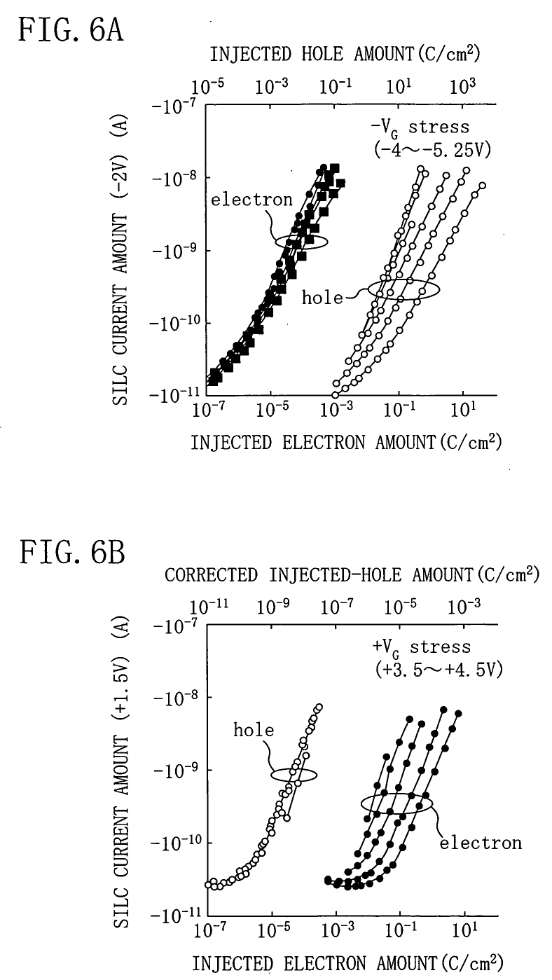

FIGS. 6A and 6B show results of plotting changes of an SILC amount at a given gate voltage in a case where various stress gate voltages are repeatedly applied to the same sample as that used for evaluations shown in FIGS. 5A and 5B. FIG. 6A shows a result obtained in a case where a negative bias stress gate voltage (−V_{G}=−4 to −5.25V) is applied. FIG. 6B shows a result obtained in a case where a positive bias stress gate voltage (+V_{G}=+3.5 to +4.5V) is applied. The SILC amount herein is defined as a gate current amount at a given gate voltage. The mechanism, for example, for conduction thereof is not specifically limited.

It is considered that the SILC amount is affected by the total amount of defects (traps) generated in an insulating film and dielectric breakdown occurs when a certain amount of such defects are generated. Therefore, if it is possible to express the behavior of the SILC amount by using the amount of injected holes or electrons, it is expected that occurrence of dielectric breakdown is controlled by these carries. In FIGS. 6A and 6B, the given gate voltages at which the SILC amount is read are, for example, −2V and +1.5V, respectively. In FIGS. 6A and 6B, solid circles (and solid squares) represent the SILC amount plotted with respect to the injected electron amount (lower abscissa) and open circles represent the SILC amount plotted with respect to the injected hole amount (upper abscissa).

First, as shown in FIG. 6A, in the case where a negative bias stress gate voltage (−V_{G}=−4 to −5.25V) is applied, the results of plotting the SILC amount with respect to the amount of injected holes, which are dominant carriers, are dispersed depending on the stress voltage, whereas the results of plotting the SILC amount with respect to the amount of injected electrons, which are subordinate carriers, form a substantially single curve. Accordingly, it is shown that the SILC amount is determined by the injected electron amount. One of the curves of the SILC amount indicated by solid circles and squares deviating to the right from the others is data obtained under application of a stress voltage of −4V and corresponds to data in the stress voltage range where Rₛ deviates (is larger than) the broken line (i.e., the line fitted to Rₛ in the high-voltage range) in the gate voltage dependence of Rₛ shown in FIG. 5A. This means that the current amount of subordinate carrier is overestimated (i.e., an “originally-injected current” described later is included in the current amount of subordinate carrier). If this overestimation is corrected, the injected electron amount is reduced to substantially match the SILC amount distribution under the other stress conditions.

Next, as shown in FIG. 6B, in the case where a positive bias stress gate voltage (+V_{G}=+3.5 to +4.5V) is applied, the results of plotting the SILC amount with respect to the amount of injected electrons, which are dominant carriers, are dispersed depending on the stress voltage, whereas the results of plotting the SILC amount with respect to the amount of injected holes, which are subordinate carriers, form a substantially single curve. In FIG. 6B, to correct a deviation from the Rₛ line (i.e., the broken line shown in FIG. 5A), the injected hole amount is calculated by using, as Rₛ, a value obtained from the line in the stress-voltage range where the deviation occurs, and the result is represented as the corrected injected-hole amount. Such a correction enables the results of plotting the SILC amount to closely match each other as shown in FIG. 6B.

From the foregoing results, it is found that values obtained by extrapolating Rₛ in the high-voltage range as Rₛ in the low-voltage range should be used. In addition, it is also found that the total amount of subordinate carriers injected until dielectric breakdown occurs can be thought to be constant.

The reason why the current amount of subordinate carrier should be corrected as described above is considered to be because of the following reasons. Subordinate carrier current contains a component generated by a mechanism described below and injected in an insulating film, in addition to originally-injected current. Specifically, when dominant carriers are injected in an insulating film from one interface thereof and reach the other interface, a certain proportion of carriers of a type different from dominant carriers (i.e., of the same type as subordinate carriers) are generated. Suppose some of these generated carriers injected in the insulating film are defined as intrinsic subordinate carriers and the current amount thereof is defined as the current amount of intrinsic subordinate carrier, the current amount of subordinate carrier is the sum of the amount of intrinsic subordinate carriers generated and injected by the above mechanism and the amount of subordinate carriers injected independently of the mechanism (i.e., originally-injected current).

Suppose the total amount of injected intrinsic subordinate carriers is defined as the total current amount of intrinsic subordinate carrier injected until a certain time, if the total amount of injected subordinate carriers obtained by measurement is substantially equal to the total amount of injected intrinsic subordinate carriers, this total amount of injected subordinate carriers obtained by measurement may be used as the total amount of injected subordinate carriers without change for lifetime prediction. On the other hand, if the total amount of injected subordinate carriers obtained by measurement is different from the total amount of injected intrinsic subordinate carriers, not the total amount of injected subordinate carriers obtained by measurement but the total amount of injected intrinsic subordinate carriers is preferably used as the total amount of injected subordinate carriers for lifetime prediction.

In the same manner, if the current amount of subordinate carrier obtained by measurement is substantially equal to the current amount of intrinsic subordinate carrier, this current amount of subordinate carrier obtained by measurement may be used as the current amount of subordinate carrier without change for lifetime prediction. On the other hand, if the current amount of subordinate carrier obtained by measurement is different from the current amount of intrinsic subordinate carrier, not the current amount of subordinate carrier obtained by measurement but the current amount of intrinsic subordinate carrier is preferably used as the current amount of subordinate carrier for lifetime prediction.

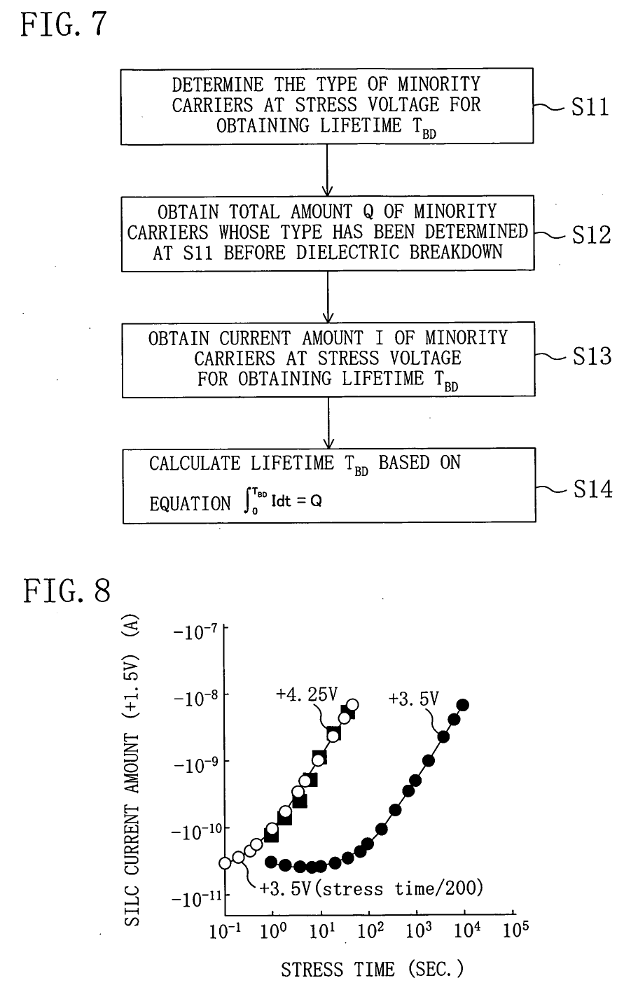

Hereinafter, a method for predicting the lifetime of an insulating film (a method for evaluating a semiconductor device) according to the first embodiment based on the foregoing findings will be described will be described with reference to FIG. 7.

FIG. 7 shows a flow of a method for evaluating a semiconductor device (a method for predicting the lifetime of an insulating film) according to the first embodiment.

First, at step S11, the type of subordinate carrier in current flowing through an insulating film sample under application of a stress voltage at which the lifetime T_{BD} of a target insulating film (e.g., a gate insulating film including a portion having a dielectric constant higher than a silicon oxide film) is to be obtained is determined. In this case, a carrier separation method, for example, may be used.

Next, at step S12, under an arbitrary condition such as a constant-voltage stress or a constant current stress, a stress is applied to the insulating film sample to cause dielectric breakdown so that the total amount Q of subordinate carriers injected until the insulating film sample causes dielectric breakdown is obtained. To measure the total injected amount Q, a large number of Q values are obtained by using, for example, a plurality of samples and are statistically processed, and then the resultant value is used for prediction of the lifetime T_{BD} described later, thereby further increasing the accuracy in predicting the lifetime T_{BD}. Specifically, Weibull plotting, for example, may be performed on a large number of Q values obtained from a plurality of samples so that a Q value with which a failure percentage (percentage of dielectric breakdown occurrence) of 50% or about 63.2% is obtained is used for prediction of the lifetime T_{BD}. To measure the total amount Q, an insulating-film sample different from the target insulating film in thickness and process, for example, may be used or an insulating-film sample not different in thickness and process, for example, but different in lot may be used.

Then, at step S13, the current amount I of the subordinate carrier flowing through the insulating film sample under application of the stress voltage for obtaining the lifetime T_{BD} is obtained. In this case, a carrier separation method as shown in FIG. 3 or 5, for example, may be used. As the current amount I of subordinate carrier, the current amount of intrinsic subordinate carrier described above may be used instead of the current amount of subordinate carrier obtained by measurement.

Thereafter, at step S14, based on Equation (1) described above, the lifetime T_{BD} in a case where the stress voltage for obtaining lifetime T_{BD} is applied to the target insulating film is calculated. For simplicity, instead of Equation (1), the lifetime T_{BD} may be calculated from the total amount Q of injected subordinate carriers and the current amount I of subordinate carrier, using the following Equation (3) or other equations.
T_{BD}=Q/I (3)

As described above, in this embodiment, the lifetime of an insulating film to which a given stress voltage is applied is easily and accurately obtained based on the finding that the total amount Q of injected subordinate carriers is constant independently of the applied voltage.

Step S13 of this embodiment may further include the following substrate-steps. That is, a time-dependent change (a first time-dependent change) of the amount of SILC flowing through an insulating film sample to which a reference voltage is applied under electrical stress application using a first stress voltage is measured. Subsequently, a time-dependent change (a second time-dependent change) of the amount of SILC flowing through the insulating film sample to which the reference voltage is applied under electrical stress application using a second stress voltage is measured. Thereafter, based on the first and second time-dependent changes, the ratio between the deterioration amount of the insulating film sample with the first stress voltage and the deterioration amount of the insulating film sample with the second stress voltage is obtained. Then, based on this ratio, the ratio between the current amount of subordinate carrier in current flowing through the insulating film sample to which the first stress voltage is applied and the current amount of subordinate carrier in current flowing through the insulating film sample to which the second stress voltage is applied is obtained.

### EMBODIMENT 2

Hereinafter, a method for predicting the lifetime of an insulating film according to a second embodiment of the present invention will be described with reference to the drawings. This embodiment relates to a method for predicting the dielectric breakdown lifetime of a gate insulating film.

As shown in FIGS. 6A and 6B, if a time-dependent change of the SILC amount obtained by repeatedly applying a stress to a gate insulating film is plotted with respect to the total amount of injected intrinsic subordinate carriers, a single correlation is obtained with respect to stress voltage dependence.

Accordingly, the plot-result difference (ratio) obtained by plotting time-dependent changes of SILC amount with respect to, for example, the stress time, i.e., the difference (ratio) in stress time direction, between two different stress conditions reflects the difference (ratio) in dielectric breakdown lifetime depending on the stress conditions.

For example, suppose the abscissa represents the stress time on a log scale and the ordinate represents the SILC amount on a log scale, if the abscissa (stress time) representing the time-dependent change of the SILC amount under one stress condition multiplied by X substantially agrees with the time-dependent change of the SILC amount under the other stress condition, it is estimated that the dielectric breakdown lifetime under one stress condition is I/X times longer than that under the other stress condition.

FIG. 8 shows an example of a difference (ratio) in dielectric breakdown lifetime depending on the stress condition described above. Specifically, FIG. 8 shows a result obtained by plotting a time-dependent change of an SILC amount at a gate voltage of +1.5 V when constant-voltage stresses of +3.5 V and +4.25 V, respectively, are repeatedly applied to an insulating film sample. In FIG. 8, solid circles represent a time-dependent SILC change under application of a constant-voltage stress of +3.5 V and solid squares represent a time-dependent SILC change under application of a constant-voltage stress of +4.25V. The time for the SILC amount to reach a given value increases as the stress voltage decreases.

In FIG. 8, open circles represent a result of plotting the time-dependent change of the SILC amount under application of a constant-voltage stress of +3.5 V with the stress time reduced to 1/200. As shown in FIG. 8, this plot result substantially agrees with the time-dependent change of the SILC amount under application of a constant-voltage stress of +4.25 V. Specifically, it is estimated that the current amount of (intrinsic) subordinate carrier under application of a constant-voltage stress of +3.5 V is approximately 1/200 of that of (intrinsic) subordinate carrier under application of a constant-voltage stress of +4.25 V. Accordingly, from the foregoing finding that the total amount of (intrinsic) subordinate carriers injected until dielectric breakdown occurs is constant, it is estimated that the dielectric breakdown lifetime under application of a constant-voltage stress of +3.5 V is the value obtained by multiplying the dielectric breakdown lifetime under application of a constant-voltage stress of +4.25 V by the reciprocal of 1/200, i.e., is 200 times as long as the dielectric breakdown lifetime under application of a constant-voltage stress of +4.25 V. The result obtained by this estimation substantially agrees with the value estimated from the result (open circles) shown in FIG. 2. This verifies the validity of the method for lifetime prediction according to the present invention.

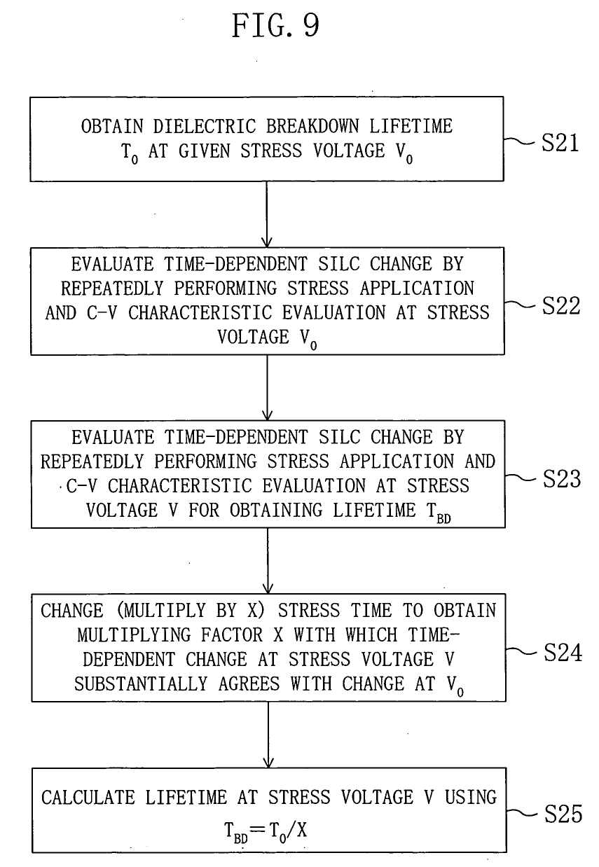

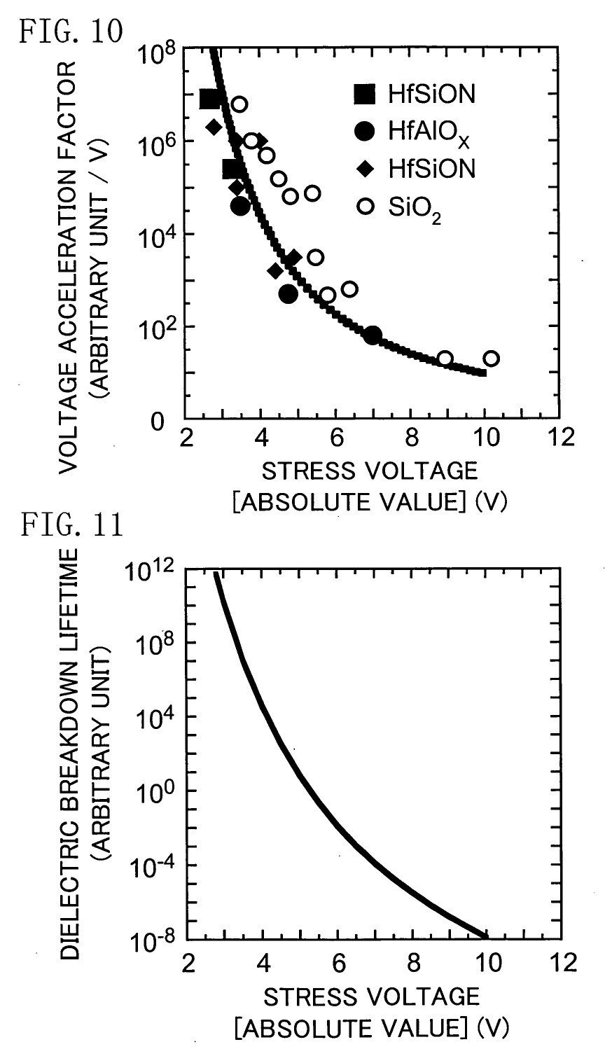

FIG. 9 shows a flow of a method for predicting the lifetime of an insulating film (e.g., a gate insulating film including a portion having a dielectric constant higher than a silicon oxide film) according to the second embodiment.

First, at step S21, the dielectric breakdown lifetime T₀ until an insulating film sample to which a given stress voltage V₀ is applied causes dielectric breakdown is obtained. The stress voltage V₀ is +4.25 V, for example.

Next, at step S22, stress application using the stress voltage V₀ and current-voltage characteristic evaluation are repeatedly performed on the insulating film sample, thereby evaluating a time-dependent change of the amount of SILC flowing through the insulating film sample. A gate voltage for measuring the SILC amount is +1.5 V, for example.

Then, at step S23, stress application using a stress voltage V at which the lifetime T_{BD} of a target insulating film is to be obtained and current-voltage characteristic evaluation are repeatedly performed on the insulating film sample, thereby evaluating a time-dependent change of the amount of SILC flowing through the insulating film sample.

Thereafter, at step S24, the stress time for the time-dependent change of the SILC amount obtained by using the stress voltage V is multiplied by a factor (e.g., X) so as to obtain a multiplying factor X with which the time-dependent change with the multiplied stress time substantially agrees with the time-dependent change of the SILC amount obtained by using the stress voltage V₀.

Lastly, at step S25, the lifetime T_{BD} in a case where the stress voltage V is applied to the garget insulating film is calculated using the following equation (4):
T_{BD}=T₀/X (4)

As described above, in this embodiment, it is possible to predict the dielectric breakdown lifetime by evaluating a stress time-dependent change of an SILC amount or a gate current amount. Accordingly, it is unnecessary to measure the time to dielectric breakdown in measurement in a low-stress voltage range, which needs enormous amounts of time, so that large reduction of the time required for measurement is enabled. In addition, the current amount of (intrinsic) subordinate carrier or the total amount of injected (intrinsic) subordinate carriers, which is needed for the lifetime prediction in the first embodiment, does not need to be measured. Accordingly, it is possible to predict the lifetime easily and accurately.

In this embodiment, current-voltage characteristics are evaluated to evaluate the time-dependent change of the SILC amount. However, voltage sweeping is not necessarily performed in a given range. That is, it is sufficient to measure only the current amount at a predetermined current-amount read voltage V_{R}.

In this embodiment, the time-dependent change of the SILC amount under each of different stress conditions is evaluated. However, the time for the current amount at a predetermined current-amount read voltage V_{R} to reach a predetermined value or changes by a predetermined value may be obtained for each of the different stress conditions so that the ratio between the resultant times under the respective stress conditions is used as the multiplying factor X.

In this embodiment, the time-dependent change of the SILC amount is evaluated for each of different stress conditions. However, the time for the voltage value at a predetermined voltage-value read current amount I_{R} to reach a predetermined value or to change by a predetermined value may be obtained for each of the different stress conditions so that the ratio between the resultant times in the respective stress conditions is used as the multiplying factor X.

### EMBODIMENT 3

Hereinafter, a method for predicting the lifetime of an insulating film according to a third embodiment of the present invention will be described with reference to the drawings. This embodiment relates to a method for predicting the dielectric breakdown lifetime of a gate insulating film.

FIG. 10 shows a result of plotting stress voltage dependence of the voltage acceleration factor γ of the dielectric breakdown lifetime (T_{BD}) of a gate insulating film made of various materials when a constant-voltage stress is applied to the gate insulating film. The voltage acceleration factor γ is expressed by the following equation (5):
γ=dlogT_{BD}/dV_{G} (5)
In Equation (5), T_{BD} is a dielectric breakdown lifetime and V_{G} is a stress voltage.

As shown in FIG. 10, regardless of the type of a material for a gate insulating film, a common correlation is observed between a voltage acceleration factor and a stress voltage (absolute value). The solid curve in FIG. 10 represents an example of a fitting result showing the correlation. According to Equation (5), it is possible to semiquantitatively obtain stress voltage dependence of the dielectric breakdown lifetime T_{BD} by integrating the stress voltage dependence of the voltage acceleration factor γ shown in FIG. 10 with respect to the stress voltage. FIG. 11 shows the stress voltage dependence of the dielectric breakdown lifetime T_{BD} (in an arbitrary unit) thus obtained.

As described above, it is possible to obtain stress voltage dependence of the dielectric breakdown lifetime (T_{BD}) based on the stress voltage dependence of the voltage acceleration factor γ in the dielectric breakdown lifetime (T_{BD}). If the obtained dependence is fitted to actually-measured T_{BD} values, a T_{BD} value in a stress voltage range (e.g., at a predetermined stress voltage) which is not actually measured is accurately obtained based on the fitting result.

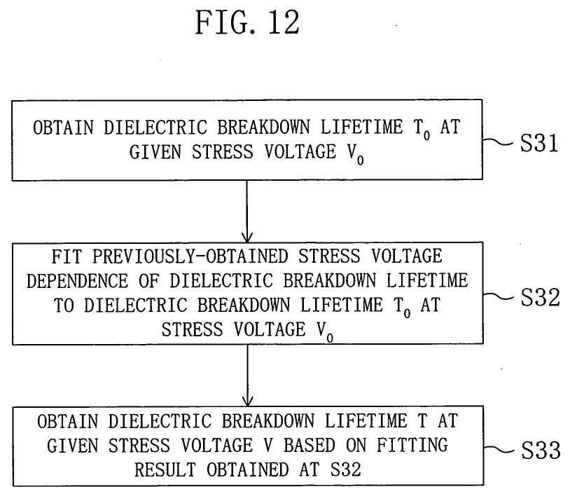

FIG. 12 shows a flow of a method for predicting the lifetime of an insulating film (e.g., a gate insulating film including a portion having a dielectric constant higher than a silicon oxide film) according to the third embodiment.

First at step S31, a dielectric breakdown lifetime T₀ until an insulating film sample to which a given stress voltage V₀ is applied causes dielectric breakdown is obtained.

Next, at step S32, previously-obtained stress voltage dependence of the dielectric breakdown lifetime of the insulating film sample is fitted to the dielectric breakdown lifetime T₀ at the stress voltage V₀ based on the foregoing findings. As stress voltage dependence of the dielectric breakdown lifetime, stress voltage dependence of the dielectric breakdown lifetime of an insulating-film sample different from the target insulating film in thickness and process, for example, or an insulating-film sample not different in thickness and process, for example, but different in lot may be previously obtained.

Lastly, at step S33, based on the fitting result obtained at step S32, a dielectric breakdown lifetime T until the insulating film sample to which a predetermined stress voltage V is applied causes dielectric breakdown is obtained.

As described above, in this embodiment, only by obtaining one or more dielectric breakdown lifetimes (T_{BD}) through actual measurement, a dielectric breakdown lifetime (T_{BD}) at a predetermined stress voltage is obtained based on stress voltage dependence of the dielectric breakdown lifetime (T_{BD}) obtained from stress voltage dependence of the voltage acceleration factor γ of the dielectric breakdown lifetime (T_{BD}), for example. Accordingly, large reduction of the time required for predicting the dielectric breakdown lifetime is enabled.

In this embodiment, stress voltage dependence of the dielectric breakdown lifetime (T_{BD}) is obtained by using stress voltage dependence of the voltage acceleration factor γ. Instead, stress voltage dependence of the dielectric breakdown lifetime (T_{BD}) may be obtained by other methods.

### EMBODIMENT 4

Hereinafter, a method for predicting the lifetime of an insulating film according to a fourth embodiment of the present invention will be described with reference to the drawings. This embodiment relates to a method for predicting the dielectric breakdown lifetime of a gate insulating film.

As described in the first embodiment, the total amount of subordinate carriers injected until a gate insulating film causes dielectric breakdown is constant regardless of the level of a stress voltage. As described in the third embodiment, it is possible to obtain stress voltage dependence of a dielectric breakdown lifetime (T_{BD}) based on the voltage acceleration factor γ of the dielectric breakdown lifetime (T_{BD}). Based on these findings, the dielectric breakdown lifetime is predicted without actual measurement.

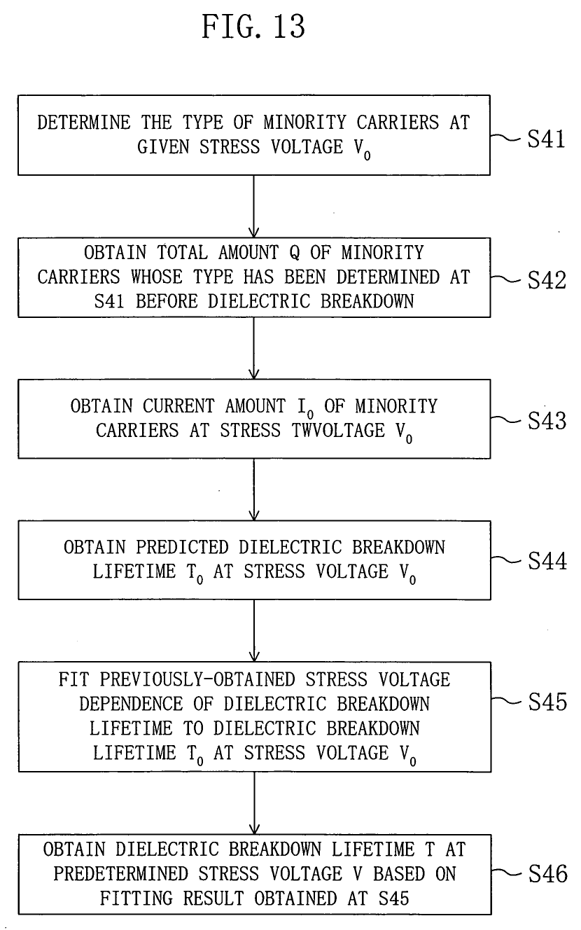

FIG. 13 shows a flow of a method for predicting the lifetime of an insulating film (e.g., a gate insulating film including a portion having a dielectric constant higher than a silicon oxide film) according to a fourth embodiment of the present invention.

First, at step S41, the type of subordinate carrier in current flowing through an insulating film sample to which a given stress voltage V₀ is applied is determined. In this case, as shown in FIG. 3 or 5, for example, a carrier separation method may be used.

Next, at step S42, the total amount Q of subordinate carriers (i.e., the subordinate carrier whose type has been determined at step S41) injected until the insulating film sample causes dielectric breakdown is obtained. To measure the total amount Q, an insulating-film sample different from the target insulating film in thickness and process, for example, may be used or an insulating-film sample not different in thickness and process, for example, but different in lot may be used.

Then, at step S43, the current amount I₀ of the subordinate carrier flowing through the insulating film sample to which the stress voltage V₀ is applied is obtained. In this case, a carrier separation method as shown in FIG. 3 or 5, for example, may be used.

Thereafter, at step S44, the obtained total amount Q and current amount I₀ are applied to, for example, Equation (1) (see, first embodiment), thereby obtaining an predicted dielectric breakdown lifetime T₀ in a case where the stress voltage V₀ is applied to the insulating film sample.

Subsequently, at step S45, stress voltage dependence of the dielectric breakdown lifetime of the insulating film sample which has been previously obtained in the same manner as that in the third embodiment is fitted to the dielectric breakdown lifetime T₀ at the stress voltage V₀. As stress voltage dependence of the dielectric breakdown lifetime, stress voltage dependence of the dielectric breakdown lifetime of an insulating-film sample different from the target insulating film in thickness and process, for example, or an insulating-film sample not different in thickness and process, for example, but different in lot may be previously obtained.

Lastly, at step S46, based on the fitting result obtained at step S45, a dielectric breakdown lifetime T until the insulating film sample to which a predetermined stress voltage V is applied causes dielectric breakdown is obtained.

As described above, in this embodiment, even without actually measuring one dielectric breakdown lifetime (T_{BD}), it is possible to predict a dielectric breakdown lifetime (T_{BD}) under a predetermined stress voltage based on stress voltage dependence of the dielectric breakdown lifetime (T_{BD}) obtained from stress voltage dependence of the voltage acceleration factor γ of the dielectric breakdown lifetime (T_{BD}), for example. Accordingly, large reduction of the time required for predicting the dielectric breakdown lifetime is enabled.

In this embodiment, in a case where the current amount of subordinate carrier obtained by measurement is substantially equal to the current amount of intrinsic subordinate carrier, this current amount of subordinate carrier obtained by measurement may be used as the current amount of subordinate carrier. In the other case, however, not the current amount of subordinate carrier obtained by measurement but the current amount of intrinsic subordinate carrier is preferably used as the current amount of subordinate carrier.

As described in the first embodiment, the total amount of subordinate carriers injected until a gate insulating film causes dielectric breakdown is constant regardless of the level of a stress voltage. As described in the third embodiment, it is possible to obtain stress voltage dependence of a dielectric breakdown lifetime (T_{BD}) based on the voltage acceleration factor γ of the dielectric breakdown lifetime (T_{BD}). Based on these findings, the current amount of intrinsic subordinate carrier is estimated even in a sample in which it is difficult to actually measure the current amount of intrinsic subordinate carrier because a current mode other than intrinsic subordinate carrier current is dominant.

Specifically, the value (total injected amount) obtained by integrating the current amount of intrinsic subordinate carrier by the time to dielectric breakdown is constant independently of a stress voltage. Based on this finding, it is estimated that the reciprocal of the dielectric breakdown lifetime (T_{BD}) is proportional to the current amount of intrinsic subordinate carrier. Accordingly, stress voltage dependence of the current amount of intrinsic subordinate carrier is obtained by obtaining the reciprocal of stress voltage dependence of the dielectric breakdown lifetime (T_{BD}) as shown in FIG. 11. It should be noted that the current amount of intrinsic subordinate carrier obtained in this manner is a semiquantitative value. In addition, the total amount of injected intrinsic subordinate carriers can be obtained as the integral of the current amount of intrinsic subordinate carrier to a given stress time.

What is claimed is:

1. A method for predicting a lifetime of an insulating film, the method being a method for predicting a dielectric breakdown lifetime of a target insulating film including a portion having a dielectric constant higher than that of a silicon oxide film, the method comprising the steps of:
(a) determining the type of subordinate carrier in current flowing through the target insulating film;
(b) obtaining the total amount of subordinate carriers injected until the target insulating film to which a given voltage is applied causes dielectric breakdown;
(c) obtaining the current amount of the subordinate carrier flowing through the target insulating film to which a predetermined voltage is applied; and
(d) obtaining a dielectric breakdown lifetime until the target insulating film to which the predetermined voltage is applied causes dielectric breakdown, based on the finding that the total amount obtained at the step (b) is constant regardless of the applied voltage and based on the current amount obtained at the step (c).

2. The method of claim 1, wherein the step (c) further comprises the steps of:
(e) measuring a time-dependent change of the amount of SILC flowing through the target insulating film to which a reference voltage is applied, the time-dependent change occurring under electrical stress application using a first stress voltage;
(f) measuring a time-dependent change of the amount of SILC flowing through the target insulating film to which the reference voltage is applied, the time-dependent change occurring under electrical application using a second stress voltage;
(g) obtaining the ratio between the amount of deterioration of the target insulating film caused by application of the first stress voltage and the amount of deterioration of the target insulating film caused by application of the second stress voltage, based on the time-dependent changes of the SILC amount measured at the steps (e) and (f); and
(h) obtaining the ratio between the current amount of the subordinate carrier in current flowing through the target insulating film to which the first stress voltage is applied and the current amount of the subordinate carrier in current flowing through the target insulating film to which the second stress voltage is applied, based on the ratio obtained at the step (g).

3. The method of claim 1, wherein the portion having a high dielectric constant is a high-k film.

4. The method of claim 1, wherein the total amount of injected intrinsic subordinate carriers is used as the total amount of the injected subordinate carriers.

5. The method of claim 1, wherein the current amount of intrinsic subordinate carrier is used as the current amount of the subordinate carrier.

6. The method of claim 2, wherein the portion having a high dielectric constant is a high-k film.

7. The method of claim 2, wherein the total amount of injected intrinsic subordinate carriers is used as the total amount of the injected subordinate carriers.

8. The method of claim 2, wherein the current amount of intrinsic subordinate carrier is used as the current amount of the subordinate carrier.

9. A method for predicting a lifetime of an insulating film, the method being a method for predicting a dielectric breakdown lifetime of a target insulating film including a portion having a dielectric constant higher than that of a silicon oxide film, the method comprising the steps of:
(a) obtaining a dielectric breakdown lifetime until the target insulating film causes dielectric breakdown under electrical stress application using a first stress voltage;
(b) evaluating a time-dependent change of the amount of current flowing through the target insulating film to which a reference voltage is applied, the time-dependent change occurring under electrical stress application using the first stress voltage;
(c) evaluating a time-dependent change of the amount of current flowing through the target insulating film to which the reference voltage is applied, the time-dependent change occurring under electrical stress application using a second stress voltage;
(d) obtaining the ratio between the amount of deterioration of the target insulating film caused by application of the first stress voltage and the amount of deterioration of the target insulating film caused by application of the second stress voltage, based on the time-dependent changes evaluated at the steps (b) and (c); and
(e) obtaining a dielectric breakdown lifetime until the target insulating film causes dielectric breakdown under electrical stress application using the second stress voltage, based on the dielectric breakdown lifetime obtained at the step (a) and the ratio obtained at the step (d).

10. The method of claim 9, wherein the portion having a high dielectric constant is a high-k film.

11. A method for predicting a lifetime of an insulating film, the method being a method for predicting a dielectric breakdown lifetime of a target insulating film including a portion having a dielectric constant higher than that of a silicon oxide film, the method comprising the steps of:
(a) determining the type of subordinate carrier in current flowing through the target insulating film;
(b) obtaining the total amount Q of subordinate carriers injected until an insulating-film sample causes dielectric breakdown under electrical stress application to the insulating-film sample;
(c) obtaining the current amount I of the subordinate carrier flowing through the target insulating film to which a stress voltage at which a lifetime T_{BD} of the target insulating film is to be obtained is applied; and
(d) calculating the lifetime T_{BD} based on Equation (1):
∫₀^{T}^{_{BD}}Idt=Q (1)

12. The method of claim 1, wherein the portion having a high dielectric constant is a high-k film.

13. The method of claim 1, wherein the total amount of injected intrinsic subordinate carriers is used as the total amount of the injected subordinate carriers.

14. The method of claim 1, wherein the current amount of intrinsic subordinate carrier is used as the current amount of the subordinate carrier.

15. A method for predicting a lifetime of an insulating film, the method being a method for predicting a dielectric breakdown lifetime of a target insulating film including a portion having a dielectric constant higher than that of a silicon oxide film, the method comprising the steps of:
(a) obtaining a dielectric breakdown lifetime T₀ until the target insulating film causes dielectric breakdown under application of a given stress voltage V₀ to the target insulating film;
(b) repeatedly performing electrical stress application using the given stress voltage V₀ and current-voltage characteristic evaluation on the target insulating film, thereby evaluating a time-dependent change of the amount of SILC flowing through the target insulating film;
(c) repeatedly performing electrical stress application using a stress voltage V at which a lifetime T_{BD} of the target insulating film is to be obtained and current-voltage characteristic evaluation on the target insulating film, thereby evaluating a time-dependent change of the amount of SILC flowing through the target insulating film;
(d) multiplying a stress time for the time-dependent change of the SILC amount obtained at the step (c) by a given factor, thereby obtaining a multiplying factor X with which the time-dependent change with the multiplied stress time substantially agrees with the time-dependent change of the SILC amount obtained at the step (b); and
(e) calculating the lifetime T_{BD} based on Equation (2):
T_{BD}=T₀/X (2)

16. The method of claim 15, wherein the portion having a high dielectric constant is a high-k film.

17. A method for predicting a lifetime of an insulating film, the method being a method for predicting a dielectric breakdown lifetime of a target insulating film including a portion having a dielectric constant higher than that of a silicon oxide film, the method comprising the steps of:
(a) obtaining a dielectric breakdown lifetime T₀ until the target insulating film to which a given stress voltage V₀ is applied causes dielectric breakdown;
(b) fitting previously-obtained stress voltage dependence of a dielectric breakdown lifetime of an insulating-film sample, to the dielectric breakdown lifetime T₀ of the target insulating film at the given stress voltage V₀; and
(c) obtaining a dielectric breakdown lifetime T_{BD} until the target insulating film to which a predetermined stress voltage V is applied causes dielectric breakdown, based on the result of the fitting.

18. The method of claim 17, wherein in the step (b), the stress voltage dependence of the dielectric breakdown lifetime of the insulating-film sample is obtained based on stress voltage dependence of the voltage acceleration factor of the dielectric breakdown lifetime of the insulating-film sample.

19. The method of claim 17, wherein the portion having a high dielectric constant is a high-k film.

20. A method for predicting a lifetime of an insulating film, the method being a method for predicting a dielectric breakdown lifetime of a target insulating film including a portion having a dielectric constant higher than that of a silicon oxide film, the method comprising the steps of:
(a) determining the type of subordinate carrier in current flowing through the target insulating film;
(b) obtaining the total amount of subordinate carriers injected until an insulating-film sample causes dielectric breakdown;
(c) obtaining the current amount of the subordinate carrier flowing through the target insulating film to which a given voltage is applied;
(d) obtaining a dielectric breakdown lifetime until the target insulating film to which the given voltage is applied causes dielectric breakdown, based on the finding that the total amount obtained at the step (b) is constant regardless of the applied voltage and based on the current amount obtained at the step (c); and
(e) fitting previously-obtained stress voltage dependence of a dielectric breakdown lifetime of an insulating-film sample, to the dielectric breakdown lifetime at the given voltage obtained at the step (d); and
(f) obtaining a dielectric breakdown lifetime until the target insulating film to which a predetermined stress voltage V is applied causes dielectric breakdown, based on the result of the fitting.

21. The method of claim 20, wherein the portion having a high dielectric constant is a high-k film.

22. The method of claim 20, wherein the total amount of injected intrinsic subordinate carriers is used as the total amount of the injected subordinate carriers.

23. The method of claim 20, wherein the current amount of intrinsic subordinate carrier is used as the current amount of the subordinate carrier.
